(19) United States
(12) Patent Application Publication
(10) Pub. No.: US 2012/0027542 A1
(43) Pub. Date: Feb. 2, 2012

(54) Vacuum processor

(76) Inventors: Ryoichi Isomura, Kudamatsu (JP); Susumu Tauchi, Shunan (JP); Hideaki Kondo, Kudamatsu (JP)

(21) Appl. No.: 12/805,837

(22) Filed: Aug. 20, 2010

(30) Foreign Application Priority Data
Jul. 27, 2010 (JP) 2010-167689

(51) Int. Cl. H01L 21/677; H01L 21/673

(52) U.S. Cl. 414/217

(57) ABSTRACT

A vacuum processor includes a first transfer vessel that is connected on the back of a lock chamber connected on the back of an atmospheric transfer vessel and has a first robot; a second transfer vessel that is arranged at the back of this first transfer vessel, connected to the first transfer vessel, and has a second robot; a repeating vessel that connects the transfer vessels, and has a storage section in which the wafer is transferred between the robots; and a processing vessel that is connected, on an almost perpendicular side, to the repeating vessel around the second transfer vessel and in which the wafer is processed at a processing chamber, wherein the first robot has two arms that are expanded and contracted to both directions across a pivot axis, and the second robot has two arms that are expanded and contracted to the same direction around the pivot axis.

### BACKGROUND OF THE INVENTION

The present invention relates to a vacuum processor that transfers a substrate-shaped sample of a semiconductor wafer to a processing chamber of a vacuum vessel inside and arranges the sample to process it using plasma formed in the processing chamber, and more particularly, to a vacuum processor including a transferring means with a plurality of arms in a transfer vessel to which a plurality of vacuum vessels are connected and in which a sample is transferred in the vacuum inside.

In the above-described apparatus, in particular, in an apparatus for processing a processing object in a depressurized apparatus, an improvement in processing efficiency of a substrate to be processed is demanded along with miniaturization and precision of processing. For this reason, in recent years, a multi-chamber apparatus in which a plurality of processing chambers are connected to one apparatus and included is developed and efficiency of productivity per installation area of a clean room is improved.

In the above-described apparatus including a plurality of processing chambers or chambers and performing a processing, each processing chamber or chamber is connected to a transfer chamber in which an internal gas or its pressure is adjusted so as to be depressurized and a robot arm for transferring a substrate is included. As the above-described example of a conventional technique, there is known a technique disclosed in JP-A-2007-511104.

In the above-described configuration of a conventional technique, a size of the entire vacuum processor is determined based on a size and arrangement of a vacuum transfer chamber and a vacuum chamber. A size of the vacuum transfer chamber is determined based on the number of connections of adjacent transfer chambers or processing chambers, a turning radius of a transfer robot in the inside, and a wafer size. Further, a size of the vacuum chamber is determined based on a wafer size, exhaust efficiency, and an arrangement of a device class necessary for a wafer processing. An arrangement of the vacuum transfer chamber and the vacuum chamber is determined based on the number of processing chambers necessary for production and a maintenance property.

### SUMMARY OF THE INVENTION

In the above-described conventional technique, adequate consideration is lacking about the following points.

Specifically, as to an arrangement of units configuring a vacuum processor, a processing chamber for processing a wafer to be processed and a vacuum transfer chamber for a vacuum transfer are not arranged such that efficiency of productivity is optimized, and the amount of production per installation area is not optimized.

In the above-described conventional technique, a processing capacity of a wafer per installation area of the vacuum processor is impaired.

In view of the foregoing, it is an object of the present invention to provide a semiconductor manufacturing equipment with high productivity per installation area.

To accomplish the above-described objects, according to one aspect of the present invention, there is provided a vacuum processor. This vacuum processor includes: an atmospheric transfer vessel in which cassette tables on which cassettes having stored therein wafers to be processed are mounted are arranged at the front surface side and the wafer is transferred under an atmospheric pressure inside; at least one lock chamber that is connected to the atmospheric transfer vessel on the back surface side of this atmospheric transfer vessel, arranged in parallel, and can adjust an internal pressure so as to store the wafer between an atmosphere pressure and a depressurized pressure; a first robot that transfers the wafer; a first transfer vessel that is connected to the lock chamber on the backward side of the lock chamber and has the first robot in the inside depressurized to the predetermined degree of vacuum; a second robot that transfers the wafer; a second transfer vessel that is arranged at the backward side of this first transfer chamber, connected to the first transfer chamber, and has the second robot in the inside depressurized to the degree of vacuum; a storage section in which the wafer is transferred between the first and second robots; a repeating vessel that connects the first transfer vessel and the second transfer vessel, arranged, and has the storage section in the inside airtightly sealed at the opposite side of the lock chamber across the first transfer vessel between the first transfer vessel and the second transfer vessel; and a processing vessel that is connected, on an almost perpendicular side, to the repeating vessel around the second transfer vessel and in which the wafer is processed at an internal processing chamber, wherein the first robot has two arms that are arranged so as to be rotated around axes in which each end is arranged within the first transfer vessel, have wafer holding sections at points, and expanded and contracted in both the directions across the axes to thereby move the wafer holding sections; and wherein the second robot has two arms that are arranged so as to be rotated around axes in which each end is arranged within the second transfer vessel, have wafer holding sections at points, and expanded and contracted in the same direction around the axes to thereby move the wafer holding sections.

According to another aspect of the present invention, the wafer holding sections of the two arms of the first or second robot are arranged at different positions in the vertical direction.

According to yet another aspect of the present invention, the first robot holds a wafer on each of two wafer holding sections and takes in or out the wafer in parallel to the repeating chamber and the lock chamber.

According to yet another aspect of the present invention, the second robot holding a not-yet processed wafer in the wafer holding section of any one of the arms expands and contracts the other arm, receives a previously-processed wafer within the processing chamber on the wafer holding section, and then expands and contracts the one arm, and transfers the not-yet processed wafer into the processing chamber to thereby exchange the not-yet processed wafer and the previously-processed wafer.

According to yet another aspect of the present invention, the vacuum processor further includes a plurality of valves that release or airtightly block a path arranged between the processing vessel and the second transfer vessel, and between the first and second transfer vessels, and communicated between these vessels, wherein operations are adjusted such that these valves exclusively release the processing vessel inside.

### BRIEF DESCRIPTION OF THE DRAWINGS

These and other features, objects and advantages of the present invention will become more apparent from the following description when taken in conjunction with the accompanying drawings wherein:

FIG. 1 is a top view illustrating an outline of a configuration of the entire vacuum processor according to an embodiment of the present invention;

FIGS. 2A and 2B are schematic views illustrating in an enlarged state a configuration of a first vacuum transfer chamber and its environment of the vacuum processor illustrated in FIG. 1 according to the present embodiment; and

FIGS. 3A and 3B are schematic views illustrating in an enlarged state a configuration of a second vacuum transfer chamber and its environment of the vacuum processor illustrated in FIG. 1 according to the present embodiment.

### DETAILED DESCRIPTION OF THE INVENTION

Hereinafter, preferred embodiments of a vacuum processor according to the present invention will be described in detail with reference to the accompanying drawings of the embodiments.

### Embodiment

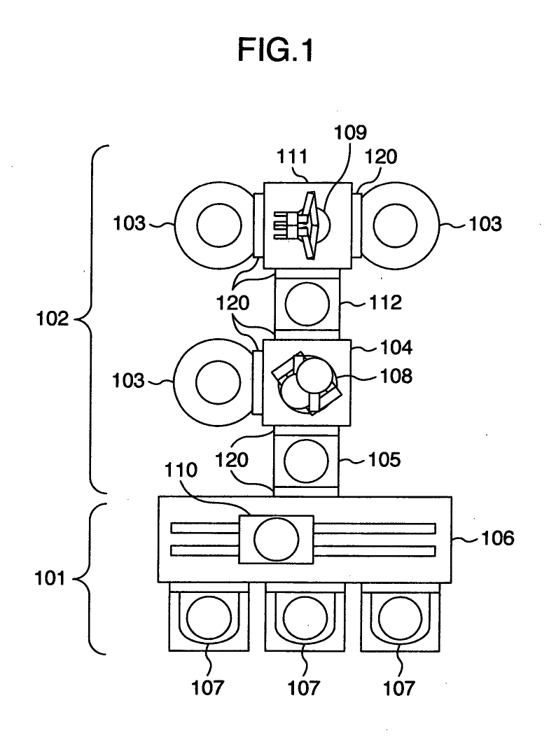

Hereinafter, preferred embodiments of the present invention will be described with reference to FIGS. 1 to 3B. FIG. 1 is a top view illustrating an outline of a configuration of the entire vacuum processor according to the embodiment of the present invention.

The vacuum processor 100 including a vacuum chamber illustrated in FIG. 1 according to the embodiment of the present invention is roughly divided into an atmospheric air side block 101 and a vacuum side block 102. The atmospheric air side block 101 is a portion for transferring a semiconductor wafer as a member to be processed and determining a storage position under an atmospheric pressure. On the other hand, the vacuum side block 102 is a block for transferring substrate-shaped samples such as wafers under a pressure depressurized from an atmospheric pressure and performing processing in the predetermined vacuum chamber.

Further, between the atmospheric air side block 101 and the above-described vacuum side block 102 for performing a transfer and processing, the vacuum processor 100 includes a portion that moves up and down a pressure between an atmospheric pressure and a vacuum pressure in a state of holding a sample inside. The vacuum processor 100 according to the present embodiment has a configuration in which a neck of a transfer time at each portion is eliminated in a state where the transfer time of the vacuum side block 102 is long as compared with that of atmospheric air side block 101.

The atmospheric air side block 101 includes an almost rectangular parallelepiped-shaped chassis 106 having an atmospheric transfer robot 110 inside. Further, the atmospheric air side block 101 includes a plurality of cassette tables 107 fixed to a front surface side of this chassis 106 and having mounted thereon cassettes in which samples as a member to be processed for processing or cleaning are stored.

The vacuum side block 102 includes one or a plurality of lock chambers 105 that are arranged between the atmospheric air side block 101 and a first vacuum transfer chamber 104 that has a space in which a sample is transferred at the inside depressurized within a vacuum vessel, and that exchanges a pressure between an atmospheric pressure and a vacuum pressure in a state where a sample for exchanging between the atmospheric air side and the vacuum side is included inside. The first vacuum transfer chamber 104 includes a rectangular parallelepiped in which a planar shape viewed from above is rectangular or an end shape of a level regarded as the rectangular parallelepiped, and the vacuum processing vessel including a vacuum chamber 103 for processing samples is connected to a plurality of sidewalls equal to each side of the rectangle so as to be attachable and detachable.

According to the present embodiment, one vacuum processing vessel is connected to one sidewall of the vacuum transfer vessels configuring the first vacuum transfer chamber 104. Further, the vacuum side block 102 includes a vacuum transfer intermediate chamber 112 that is arranged at another side between a second vacuum transfer chamber 111 and the first vacuum transfer chamber 104, and in which a sample transferred through these portions is temporarily stored and held and then exchanged from one side to the other side. Also, the vacuum transfer intermediate chamber 112 is arranged in the vacuum vessel and the inside thereof is adjusted to pressures of the same degree of vacuum as those of the first and second vacuum transfer chambers 104 and 111.

Further, to one side end of the vacuum transfer intermediate chamber 112, the first vacuum transfer chamber 104 is connected and both of internal portions thereof are connected via a path so as to be communicated with each other. To the other end opposing to this path, the second vacuum transfer chamber 111 is connected so that both of internal parts can be communicated with each other. Also, a vacuum vessel including the second vacuum transfer chamber 111 has a rectangular parallelepiped shape in which a planar shape is rectangular similarly to a case of the first vacuum transfer chamber 110. Further, the vacuum side block 102 has a configuration in which the vacuum processing vessel including the vacuum chamber 103 can be connected to each of three sidewalls except the sidewall to which the vacuum transfer intermediate chamber 112 is connected so as to be attachable and detachable. According to the present embodiment, two vacuum processing vessels are connected to sidewalls equal to two sides.

As described above, the number of the vacuum chambers 103 connected to the first vacuum transfer chamber 104 is smaller than that of the vacuum chambers 103 connected to the second vacuum transfer chamber 111. This vacuum side block 102 is a block configured by a plurality of vacuum vessels capable of depressurizing the entire vacuum vessel and maintaining a pressure with the high degree of vacuum.

Each internal portion of the first vacuum transfer chamber 104 and the second vacuum transfer chamber 111 is connected and communicated with the transfer chamber. The first vacuum transfer chamber 104 has a separate-drive vacuum transfer robot 108 that transfers a sample under the depressurized vacuum between the lock chamber 105, the vacuum chamber 103, and the second vacuum transfer intermediate chamber 112. On the other side, the second vacuum transfer chamber 111 has a connecting type vacuum transfer robot 109 that transfers a sample between the vacuum chamber 103 and the vacuum transfer intermediate chamber 112 and is arranged at the center of the second vacuum transfer chamber 111.

In the first vacuum transfer chamber 104, the separate-drive vacuum transfer robot 108 takes in or out a sample, in a state where the sample is mounted on its arms, between a sample stage arranged in the vacuum chamber 103 and any one of the lock chamber 105 and the vacuum transfer intermediate chamber 112. Similarly, in the second vacuum transfer chamber 111, the connecting type vacuum transfer robot 109 takes in or out a sample, in a state where the sample is mounted on its arms, between a sample stage arranged in the vacuum chamber 103 and the vacuum transfer intermediate chamber 112. A path communicated via a valve 120 capable of airtightly blocking and releasing chambers is provided between the first vacuum transfer chamber 104 and any one of the vacuum chamber 103, the lock chamber 105, and the vacuum transfer intermediate chamber 112, and between the second vacuum transfer chamber 111 and any one of the vacuum chamber 103 and the vacuum transfer intermediate chamber 112, respectively. This path is opened and closed using the valve 120.

Next, there will be described an outline of a transfer process of a sample at the time of processing the sample by using the above-described configured vacuum processor. A processing is started by receiving a command from a control device (not illustrated) that is connected to a predetermined portion of the vacuum processor 100 using somewhat communication method and adjusts an operation of vacuum processor 100, or receiving a command from a control device of a manufacturing line on which the vacuum processor 100 is provided with regard to substrate-shaped samples such as a plurality of semiconductor wafers stored in a cassette mounted on any one of the cassette tables 107. The atmospheric transfer robot 110 receiving a command from the control device takes out the sample previously specified by the command from the cassette and transfers it through an atmospheric air transfer chamber as a space for the transfer in the chassis 106 to thereby take it in the lock chamber 105.

The lock chamber 105 in which a sample is transferred and stored is blocked and sealed by the valve 120 and depressurized up to a predetermined pressure in a state where the transferred sample is stored. Subsequently, the valve 120 on the side opposite to the first vacuum transfer chamber 104 is released, and the lock chamber 105 and a transfer chamber of the first vacuum transfer chamber 104 are communicated with each other. The separate-drive vacuum transfer robot 108 expands its arm into the lock chamber 105 and transfers the sample of the lock chamber 105 to the first vacuum transfer chamber 104 side. Further, the separate-drive vacuum transfer robot 108 takes the sample mounted on its arm in any one of the predetermined vacuum chamber 103 and the vacuum transfer intermediate chamber 112 at the time of taking out it from the cassette.

According to the present embodiment, a plurality of valves 120 that release and block the communication between the first and second vacuum transfer chambers 104 and 111 and the chambers connected thereto are exclusively opened and closed. Specifically, as for the sample transferred to the vacuum transfer intermediate chamber 112, the valve 120 that is opened and closed between the vacuum transfer intermediate chamber 112 and the first vacuum transfer chamber 104 is closed and the vacuum transfer intermediate chamber 112 is sealed with the valve 120. Subsequently, the valve 120 that is opened and closed between the vacuum transfer intermediate chamber 112 and the second vacuum transfer chamber 111 is opened, and the connecting type vacuum transfer robot 109 included in the second vacuum transfer chamber expands its arms and transfers the sample to the second vacuum transfer chamber 111. The connecting type vacuum transfer robot 109 transfers the sample mounted on its arm to any one of the predetermined vacuum chambers 103 at the time of taking out it from the cassette.

After the sample is transferred to any one of the vacuum chambers 103, the valve 120 that is opened and closed between this vacuum chamber 103 and the vacuum transfer chamber 104 is closed and the vacuum chamber 103 is sealed with the valve 120. Then, a processing gas is introduced into the processing chamber and vacuum is formed in the processing chamber to thereby process the sample.

When detecting that processing of the sample is completed, there is released the valve 120 that is opened and closed between the above-described processing chamber and a transfer chamber of the first vacuum transfer chamber 104 connected thereto or that of the second vacuum transfer chamber 111 connected thereto. Then, the separate-drive vacuum transfer robot 108 or the connecting type vacuum transfer robot 109 takes the previously-processed sample out the lock chamber 105 opposite to a case where the sample is taken in the processing chamber. When the sample is transferred to the lock chamber 105, the valve 120 that opens and closes a path for communicating this lock chamber 105 and the transfer chamber of the vacuum transfer chamber 104 is closed and the transfer chamber of the vacuum transfer chamber 104 is sealed with the valve 120 and a pressure within the lock chamber 105 rises up to an atmosphere pressure.

Subsequently, the valve 120 that airtightly seals and blocks between the lock chamber 105 and the inside of the chassis 106 is released, and the inside of the lock chamber 105 and that of the chassis 106 are communicated with each other. The atmospheric transfer robot 110 transfers the sample to the original cassette from the lock chamber 105 and returns it to the original position of the cassette.

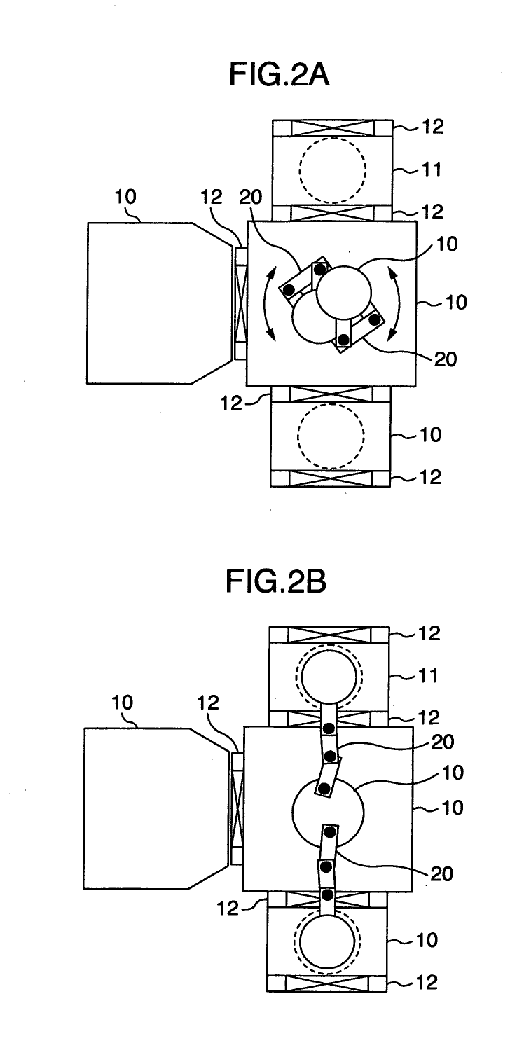

FIGS. 2A and 2B are schematic views illustrating in an enlarged state a configuration of the first vacuum transfer chamber and its environment of the vacuum processor illustrated in FIG. 1 according to the present embodiment. As illustrated in FIGS. 2A and 2B, the separate-drive vacuum transfer robot 108 has a first arm 201 and second arm 202 for transferring a sample.

The separate-drive vacuum transfer robot 108 according to the present embodiment has a configuration in which a planar system having a vertical (direction orthogonal to a paper face of the figure) pivot axis of the entire robot has a circular pedestal and ends of two arms are connected to the pedestal rotating around the pivot axis arranged at the center of this circle at a position offset to each predetermined distance in the radius direction from the pivot axis of the robot. This connection is performed so as to be rotated around the vertical (direction orthogonal to a paper face of the figure) axis. Further, as for respective arms, a first arm, a second arm, and a third arm holding a sample are connected to the axis of the end by three hinges, and further are configured so that expansion and contraction in the rotation direction, in the vertical direction, and in the horizontal direction around the vertical axis of the arm end can be operated independently.

Further, when holding the sample or transferring the sample, the separate-drive vacuum transfer robot 108 can rotate each arm around a plurality of hinges and fold it such that each arm or the held sample is prevented from interfering with a sidewall of the first vacuum transfer chamber 104, another arm, or the sample held by the another arm included in the separate-drive vacuum transfer robot 108 itself

The separate-drive vacuum transfer robot 108 according to the present embodiment is a transfer apparatus having the above-described configuration, and is configured to have a restriction in the expansion and contraction direction of the arms in the first vacuum transfer chamber. The separate-drive vacuum transfer robot 108 rotates each arm independently around the axis of its hinges and expands and contracts each arm to thereby transfer the sample only in the direction from the center of the pedestal to its end. This permits the separate-drive vacuum transfer robot 108 to expand and contract each arm in parallel and transfer the sample with regard to the lock chamber 105 and vacuum transfer intermediate chamber 112 that are connected and arranged outside the opposite sidewalls of the vacuum vessel configuring the first vacuum transfer chamber 104.

While holding the sample, the separate-drive vacuum transfer robot 108 turns around the pivot axis so as to fold each of the first arm 201 and the second arm 202, and approximate a sample-holding section arranged at its point to the pivot axis of the entire robot, and then minimize a project area at the time of folding these arms. This configuration of the separate-drive vacuum transfer robot 108 prevents an enlargement of a distance between the pivot axis or axis of the hinge of each arm end and a sample mounting place of the communicated vacuum chamber 103, lock chamber 105, and vacuum transfer intermediate chamber 112 in which a project area (an occupied area) viewed from an upper surface of the first vacuum transfer chamber 104 and capacity are reduced. Further, the configuration prevents the transfer time between the opposite portions and improves the processing or operation efficiency.

The above-described configuration permits a project area during the turning of the separate-drive vacuum transfer robot 108 to be minimized, a project area of the first vacuum transfer chamber 104 to be also reduced, and taking in and taking out of the sample to be controlled independently. Further, when accessing a transfer destination positioning in parallel in the opposite direction, productivity per installation area can be increased.

FIG. 2A illustrates a state where the separate-drive vacuum transfer robot 108 of the vacuum transfer chamber 104 contracts the first arm 201 and the second arm 202, and a state of transferring the sample.

On the other hand, FIG. 2B illustrates a state where the separate-drive vacuum transfer robot 108 expands the first arm 201 in a state where the sample is mounted on the sample-holding section of the point and transfers the sample into the vacuum transfer intermediate chamber 112 as well as expands the second arm 202 and transfers the sample into the first lock chamber 105. As described above, when expanding and contracting the first arm 201 and the second arm 202 in parallel, the first vacuum transfer robot 108 can transfer the sample in parallel with regard to two portions to which the communication is performed at positions opposite to the first vacuum transfer chamber 104 across the first vacuum transfer chamber 104.

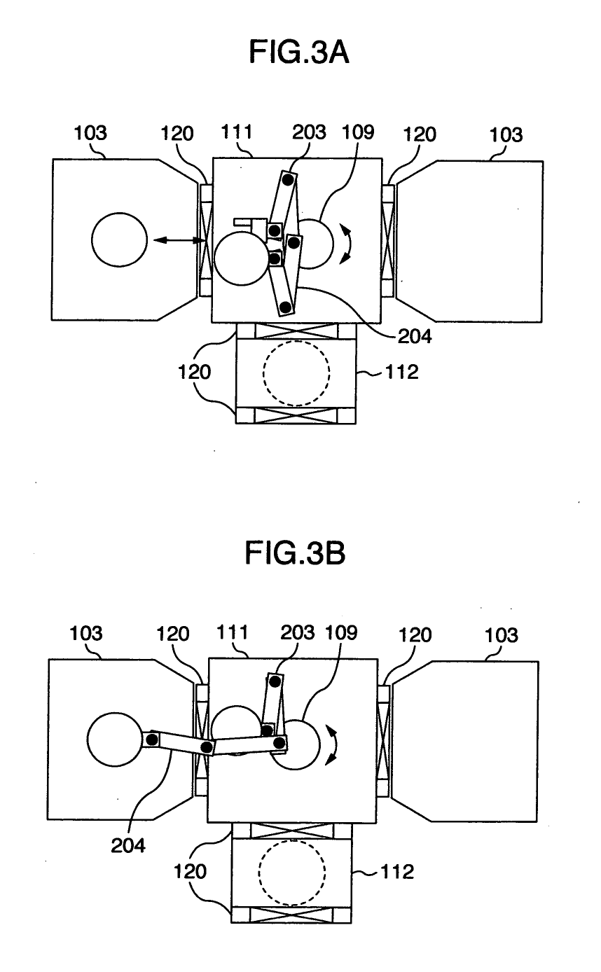

FIGS. 3A and 3B are schematic views illustrating in an enlarged state a configuration of the second vacuum transfer chamber and its environment of the vacuum processor illustrated in FIG. 1 according to the present embodiment. As illustrated in FIGS. 3A and 3B, the connecting type vacuum transfer robot 109 arranged in the second vacuum transfer chamber 111 has a first arm 203 and second arm 204 for transferring the sample, and can expand and contract them with regard to specific chambers that are connected to the second vacuum transfer chamber 111.

In the same manner as in the separate-drive vacuum transfer robot 108, the connecting type vacuum transfer robot 109 according to the present embodiment has a disk-shaped pedestal that is arranged at the center of the second vacuum transfer chamber 111 and turns around the vertical (direction orthogonal to a paper face of the figure) central axis. Further, on the pedestal, the vertical axis of the hinge being the common pivot axis to the ends of the first arm 203 and second arm 204 expanded and contracted horizontally is arranged at a position offset by a predetermined distance from the pivot axis of the entire robot arranged at the center of the pedestal. This configuration permits the connecting type vacuum transfer robot 109 to turn and expand and contract two arms in parallel with regard to the same portion.

Further, the sample holding section is arranged at the point of each arm, and also each arm has a first, second, and third beam-shaped members connected from the end using three hinges (the sample holding section is connected to a member of the point side). Further, the connecting type vacuum transfer robot 109 can expand and contract each arm independently in the vertical direction and in the horizontal direction. At the time of holding the sample or transferring the sample, the connecting type vacuum transfer robot 109 can fold the arms such that one of the respective arms or the held sample is prevented from interfering with a sidewall of the second vacuum transfer chamber 111 arranged inside by the connecting type vacuum transfer robot 109, the other arm, or the sample held by the other arm.

While holding the sample, the above-described connecting type vacuum transfer robot 109 turns around the pivot axis in a state where the first and second arms 203 and 204 are folded and the sample is approximated to the pivot axis so as to minimize the project area below. The connecting type vacuum transfer robot 109 illustrated in FIGS. 1 and 3 according to the present embodiment folds each arm so as to expand the hinges for connecting the first and second members toward the outside of the chamber with regard to the pivot axis or the end axis. However, the connecting type vacuum transfer robot 109 may fold the arm so as to retract a second hinge in the direction opposite to the direction in which each arm is expanded.

The above-described configuration permits a turning project area of the connecting type vacuum transfer robot 109 to be minimized, a project area of the second vacuum transfer chamber 111 to be also reduced, and productivity per installation area to be increased.

Further, FIG. 3A illustrates a state where the connecting type vacuum transfer robot 109 contracts each arm and transfers the sample into the second vacuum transfer chamber 111. FIG. 3B illustrates a state where the connecting type vacuum transfer robot 109 contracts the first arm 203 and takes the previously-processed sample out from the vacuum chamber 103, and then, expands the second arm 204 and takes the not-yet processed sample into the vacuum chamber 103. As described above, the connecting type vacuum transfer robot 109 according to the present embodiment can operate two arms and transfer the sample to the same portion. For example, the connecting type vacuum transfer robot 109 can exchange the previously-processed sample and the not-yet processed sample with regard to the vacuum chamber 103 or the vacuum transfer intermediate chamber 112 by continuously performing the above-described operations.

There will be described in detail below operations at the time of transferring a sample by using the separate-drive vacuum transfer robot 108 and the connecting type vacuum transfer robot 109. According to the present embodiment, the above-described robots move a sample from one transfer site to another transfer site. Suppose that the one transfer site is a transfer site A and the another transfer site is a transfer site B. At these transfer sites, normally, a sample-holding section for mounting and holding the sample is arranged, respectively. For example, when the transfer site A is the vacuum chamber 103, a sample stage that is arranged inside and that mounts and holds the sample corresponds to the sample-holding section.

A sample A is held and gets ready for the transfer in the transfer site A, and similarly a sample B gets ready for the transfer in the other transfer site B. There will be described a case where one sample stage is provided in the transfer sites A and B, respectively, and only a sheet of sample is taken in. Suppose that neither of two arms of the robot for the transfer hold the sample and one is an arm A and another is an arm B. The separate-drive vacuum transfer robot 108, an operation starts an operation from a state where the arm A faces to the direction accessible to the transfer site A. The connecting type vacuum transfer robot 109 starts an operation from a state where the arms A and B face to the direction accessible to the transfer site A. As to the number of operation steps, taking in, taking out, and turning of 90 degrees are assumed to be counted as one step.

In the configuration of the separate-drive vacuum transfer robot 108, a description will be made of the operation step of the sample transfer in the case where two transfer sites are connected to and communicated with opposite sidewalls of the transfer chamber. First, the separate-drive vacuum transfer robot 108 expands the arm A to the transfer site A and receives the sample A at the transfer site A to thereby take the sample out of here. At the same time or after an arbitrary time difference of the operation start of the arm A, the separate-drive vacuum transfer robot 108 expands the arm B to the transfer site B and similarly, takes out the received sample B. Next, the separate-drive vacuum transfer robot 108 folds each arm A and arm B, and turns at 180 degrees around the pivot axis in a state where the sample or the sample holding section of an arm point is most approximated to the pivot axis and a shape in which the project area below is minimized is maintained. Further, the separate-drive vacuum transfer robot 108 expands each arm A and arm B to the transfer sites A and B again after the turning, and takes the sample A in the transfer site B to thereby transfer it to the internal sample stage. In a similar fashion, the separate-drive vacuum transfer robot 108 transfers the sample B to the transfer site A. In the above-described operation, the number of the operation steps is four.

On the other hand, there will be described an outline of the operation step in the case where the separate-drive vacuum transfer robot 108 transfers a sample to two transfer sites positioned at right angles to each other. In this case, the separate-drive vacuum transfer robot 108 first expands the arm A to the transfer site A and takes out the sample A. The separate-drive vacuum transfer robot 108 folds the arm A holding the sample A and most approximates the sample or the sample holding section to the pivot axis, and then, turns at 90 degrees around the pivot axis up to a position in which the arm B is accessible to the transfer site B. The separate-drive vacuum transfer robot 108 turns up to a position in which the arm B is expandable to the transfer site B by the shortest distance, and then, expands the arm B and receives the sample B after penetration to the transfer site B to thereby take it out from the transfer site B.

After folding the arm B holding the sample B, the separate-drive vacuum transfer robot 108 turns at 180 degrees around the pivot axis up to a position in which the arm A is expandable to the transfer site B by the shortest distance, and then expands the arm A and takes the sample A in the transfer site B. After folding the arm A, the separate-drive vacuum transfer robot 108 turns at 90 degrees around the pivot axis up to a position in which the arm B is expandable to the transfer site A by the shortest distance. When completing the turning, the separate-drive vacuum transfer robot 108 expands the arm B and takes the sample B in the transfer site A again. As described above, as compared with the transfer in the opposite direction, the number of the operation steps is increased to eight in the transfer in the perpendicular direction.

There will be described an outline of operations for the sample transfer in the case where the transfer sites of two samples are positioned in the direction opposite to each other in the connecting type vacuum transfer robot 109. The connecting type vacuum transfer robot 109 expands one arm A to the transfer site A and takes out the sample A in two arms included therein. After folding the arm A with the sample A, the connecting type vacuum transfer robot 109 turns at 180 degrees up to a position in which the arm B is expandable to the transfer site B by the shortest distance. When turning up to a position in which the arm B is expandable to the transfer site B, the connecting type vacuum transfer robot 109 expands the arm B to the transfer site B and receives the sample B by the arm B. Then, along with this contraction of the arm B, the connecting type vacuum transfer robot 109 takes the sample B out from the transfer site B.

After folding the arm B with the sample B, the connecting type vacuum transfer robot 109 expands the arm A to the transfer site B and takes the sample A in the transfer site B. After transferring the sample A to the sample stage and folding the arm A, the connecting type vacuum transfer robot 109 turns at 180 degrees up to a position in which the arm B is expandable to the transfer site A. When turning up to a position in which the arm B is expandable to the transfer site A, the connecting type vacuum transfer robot 109 expands the arm B to the transfer site A and takes the sample A in the transfer site A to thereby transfer it to the sample stage. In this case, the number of the operation steps is eight.

Next, there will be described an outline of operations for the transfer in the case where the connecting type vacuum transfer robot 109 transfers a sample to transfer sites positioned at right angles to each other. The connecting type vacuum transfer robot 109 expands the arm A to the transfer site A, and receives and takes the sample A out from the transfer site A. After folding the arm A with the sample A, the connecting type vacuum transfer robot 109 turns at 90 degrees up to a position in which the arm B is expandable to the transfer site B. When turning up to a position in which the arm B is expandable to the transfer site B, the connecting type vacuum transfer robot 109 expands the arm B to the transfer site B and receives and takes the sample B out from the transfer site B.

After folding the arm B with the sample B, the connecting type vacuum transfer robot 109 expands the arm A to the transfer site B and takes in the sample A to thereby transfer it to the sample stage. After folding the arm A, the connecting type vacuum transfer robot 109 turns at 90 degrees up to a position in which the arm B is expandable to the transfer site A. When turning at 90 degrees up to a position in which the arm B is expandable to the transfer site A, the connecting type vacuum transfer robot 109 expands the arm B to the transfer site A and takes in the sample A to thereby transfer it. In this case, the number of the operation steps is six.

According to the present embodiment illustrated in FIG. 1, the separate-drive vacuum transfer robot 108 is arranged at the center of the first vacuum transfer chamber 104. As illustrated in FIG. 2, the separate-drive vacuum transfer robot 108 transfers the not-yet processed sample or the previously-processed sample between the lock chamber 105 and vacuum transfer intermediate chamber 112 arranged at opposite positions. One vacuum chamber 103 is arranged with facing the first vacuum transfer chamber 104, and the separate-drive vacuum transfer robot 108 transfers the not-yet processed sample or the previously-processed sample even between the lock chamber 105 and this vacuum chamber 103. In the above-described arrangement, the vacuum processor according to the present embodiment transfers the sample by using the above-described separate-drive vacuum transfer robot 108 arranged at the first vacuum transfer chamber 104 to which one or a plurality of transfer paths are connected in the opposite direction. As a result, efficiency of operations is improved and that of processings is improved.

Further, according to the present embodiment, as illustrated in FIGS. 3A and 3B, the connecting type vacuum transfer robot 109 is arranged in the second vacuum transfer chamber 111 to which two opposite vacuum chambers 103 are connected. The connecting type vacuum transfer robot 109 transfers the not-yet processed sample or the previously-processed sample in the perpendicular direction of figures between the vacuum transfer intermediate chamber 112 at a lower part of figures and the two vacuum chambers 103. As described above, according to the present embodiment, as compared with the separate-drive vacuum transfer robot 108, the connecting type vacuum transfer robot 109 can reduce the number of the operation steps required for the transfer in the perpendicular direction and transfer the sample by using the connecting type vacuum transfer robot 109 in the second vacuum transfer chamber 111 to which one or a plurality of transfer paths are connected only in the perpendicular direction. As a result, efficiency of operations is improved and that of processings is improved.

There will be described an outline of operations of the above-described vacuum processor according to the present embodiment including the separate-drive vacuum transfer robot 108 and the connecting type vacuum transfer robot 109. In FIG. 1, in the steady state, the separate-drive vacuum transfer robot 108 of the first vacuum transfer chamber 104 transfers the not-yet processed sample from the lock chamber 105 to the predetermined first vacuum transfer chamber 104. Further, the separate-drive vacuum transfer robot 108 transfers the sample processed in the vacuum chamber 103 to the lock chamber 105. To the above-described lock chamber 105 as a transfer source of the not-yet processed sample and as a transfer destination of the previously-processed sample, the vacuum transfer intermediate chamber 112 is connected in the opposite direction and the vacuum chamber 103 is connected in the perpendicular direction. In other words, the vacuum transfer robot included in the first vacuum transfer chamber 104 performs the transfer in the perpendicular direction and that in the opposite direction. The separate-drive vacuum transfer robot 108 transfers the sample to the transfer path in the opposite direction.

In FIG. 1, in the steady state, the connecting type vacuum transfer robot 109 of the second vacuum transfer chamber 111 transfers the not-yet processed sample from the vacuum lock chamber 105 through the vacuum transfer intermediate chamber 112 connected to the second vacuum transfer chamber 111 to the vacuum chamber 103 connected to the second vacuum transfer chamber 111. Further, when transferring the previously-processed sample from the vacuum chamber 103 connected to the second vacuum transfer chamber 111 to the lock chamber 105, the connecting type vacuum transfer robot 109 transfers it to the lock chamber 105 through the vacuum transfer intermediate chamber 112. To the above-described vacuum transfer intermediate chamber as a transfer source of the not-yet processed sample and as a transfer destination of the previously-processed sample, the vacuum chambers 103 are connected at two places in the perpendicular direction. In short, the connecting type vacuum transfer robot 109 included in the second vacuum transfer chamber 111 performs only the transfer in the perpendicular direction.

The proposed vacuum processor according to the present embodiment can provide a semiconductor manufacturing equipment with high productivity per installation area.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processor comprising:
an atmospheric transfer vessel in which cassette tables on which cassettes having stored therein wafers to be processed are mounted are arranged at the front surface side and the wafer is transferred under an atmospheric pressure inside;
at least one lock chamber that is connected to the atmospheric transfer vessel on the back surface side of this atmospheric transfer vessel, arranged in parallel, and can adjust an internal pressure so as to store the wafer between an atmosphere pressure and a depressurized pressure;
a first robot that transfers the wafer;
a first transfer vessel that is connected to the lock chamber on the backward side of the lock chamber and has the first robot in the inside depressurized to the predetermined degree of vacuum;
a second robot that transfers the wafer;
a second transfer vessel that is arranged at the backward side of this first transfer chamber, connected to the first transfer chamber, and has the second robot in the inside depressurized to the degree of vacuum;
a storage section in which the wafer is transferred between the first and second robots;
a repeating vessel that connects the first transfer vessel and the second transfer vessel, arranged, and has the storage section in the inside airtightly sealed at the opposite side of the lock chamber across the first transfer vessel between the first transfer vessel and the second transfer vessel; and
a processing vessel that is connected, on an almost perpendicular side, to the repeating vessel around the second transfer vessel and in which the wafer is processed at an internal processing chamber,
wherein the first robot has two arms that are arranged so as to be rotated around axes in which each end is arranged within the first transfer vessel, have wafer holding sections at points, and expanded and contracted in both the directions across the axes to thereby move the wafer holding sections; and
wherein the second robot has two arms that are arranged so as to be rotated around axes in which each end is arranged within the second transfer vessel, have wafer holding sections at points, and expanded and contracted in the same direction around the axes to thereby move the wafer holding sections.

2. The vacuum processor according to claim 1, wherein the wafer holding sections of the two arms of the first or second robot are arranged at different positions in the vertical direction.

3. The vacuum processor according to claim 1, wherein the first robot holds a wafer on each of two wafer holding sections and takes in or out the wafer in parallel to the repeating chamber and the lock chamber.

4. The vacuum processor according to claim 2, wherein the first robot holds a wafer on each of two wafer holding sections and takes in or out the wafer in parallel to the repeating chamber and the lock chamber.

5. The vacuum processor according to claim 1, wherein the second robot holding a not-yet processed wafer in the wafer holding section of any one of the arms expands and contracts the other arm, receives a previously-processed wafer within the processing chamber on the wafer holding section, and then expands and contracts the one arm, and transfers the not-yet processed wafer into the processing chamber to thereby exchange the not-yet processed wafer and the previously-processed wafer.

6. The vacuum processor according to claim 2, wherein the second robot holding a not-yet processed wafer in the wafer holding section of any one of the arms expands and contracts the other arm, receives a previously-processed wafer within the processing chamber on the wafer holding section, and then expands and contracts the one arm, and transfers the not-yet processed wafer into the processing chamber to thereby exchange the not-yet processed wafer and the previously-processed wafer.

7. The vacuum processor according to claim 3, wherein the second robot holding a not-yet processed wafer in the wafer holding section of any one of the arms expands and contracts the other arm, receives a previously-processed wafer within the processing chamber on the wafer holding section, and then expands and contracts the one arm, and transfers the not-yet processed wafer into the processing chamber to thereby exchange the not-yet processed wafer and the previously-processed wafer.

8. The vacuum processor according to claim 4, wherein the second robot holding a not-yet processed wafer in the wafer holding section of any one of the arms expands and contracts the other arm, receives a previously-processed wafer within the processing chamber on the wafer holding section, and then expands and contracts the one arm, and transfers the not-yet processed wafer into the processing chamber to thereby exchange the not-yet processed wafer and the previously-processed wafer.

9. The vacuum processor according to claim 1, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

10. The vacuum processor according to claim 2, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

11. The vacuum processor according to claim 3, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

12. The vacuum processor according to claim 4, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

13. The vacuum processor according to claim 5, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

14. The vacuum processor according to claim 6, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

15. The vacuum processor according to claim 7, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.

16. The vacuum processor according to claim 8, further comprising:
a plurality of valves that release or airtightly block a path arranged between the processing vessel and the second transfer vessel, and between the first and second transfer vessels, and communicated between these vessels,
wherein operations are adjusted such that these valves exclusively release the processing vessel inside.
